(19) United States
(12) Patent Application Publication
(10) Pub. No.: US 2026/0314111 A1
(43) Pub. Date: Oct. 8, 2026

(54) SOLAR PANEL AND VEHICLE COMPRISING SAME

(71) Applicants: Hyundai Motor Company, Seoul (KR); Kia Corporation, Seoul (KR)

(72) Inventor: Yeonghee LEE, Hwaseong-Si (KR)

(73) Assignees: Hyundai Motor Company, Seoul (KR); Kia Corporation, Seoul (KR)

(21) Appl. No.: 19/257,171

(22) Filed: Jul. 1, 2025

(30) Foreign Application Priority Data
Feb. 4, 2025 (KR) 10-2025-0013582

(51) Int. Cl. H10F 77/63; H02S 20/30; H10F 19/80

(52) U.S. Cl. CPC H10F 77/63; H02S 20/30; H10F 19/80

(57) ABSTRACT

A solar panel capable may have various shapes by including a dummy cell module, and have improved output characteristics and lifespan characteristics.

### CROSS-REFERENCE TO RELATED APPLICATION

This present application claims the benefit of priority to Korean Patent Application No. 10-2025-0013582, filed on Feb. 4, 2025, in the Korean Intellectual Property Office, the entire disclosure of which is incorporated herein by reference.

### FIELD

The present disclosure relates to a solar panel configured for including various shapes by including a dummy cell module, and including improved output characteristics and lifespan characteristics, and a vehicle including same.

### BACKGROUND

Recently, roof-type solar panels, in which solar cells are applied to vehicle roofs, are being developed. The solar cells are primarily silicon solar cells, which currently provide the highest photoelectric conversion efficiency among commercially available solar cell technologies. However, silicon solar cells are manufactured and processed into wafers from silicon ingots, and are brittle and can easily break even with slight bending. These characteristics can lead to cracking during processing when applied to highly curved or contoured vehicle panel areas, resulting in reduced output and lifespan.

In particular, when silicon solar cells are applied to areas where character lines, which are design elements of vehicle body panels e.g., hoods, doors, and lids, are emphasized, there is a high risk of cracks occurring, and thus solar cells cannot be applied to such areas.

Additionally, temperature increases in solar cells are a major cause of output degradation and lifespan reduction. Accordingly, research is ongoing on solar panels that can prevent temperature rise within the cells while being applicable to highly curved vehicle body surfaces.

### SUMMARY

The present disclosure is directed to providing a solar panel configured for having various shapes by including a dummy cell module that does not include a rear electrode, and having improved output characteristics and lifespan characteristics, and a vehicle including same.

A solar panel according to an embodiment of the present disclosure may include a heat transfer layer, a dummy cell module disposed over and spaced apart from the heat transfer layer, and a solar cell module spaced apart from the dummy cell module in a horizontal direction of the solar panel.

The dummy cell module may be electrically inactive.

A vehicle according to an embodiment of the present disclosure may include the solar panel according to various embodiments of the present disclosure.

The solar panel according to an exemplary embodiment of the present disclosure may include a dummy cell module.

The dummy cell module may be electrically inactive as it does not include a rear electrode. Accordingly, unlike existing solar cell modules, the dummy cell module may have various polygonal shapes.

As a result, the solar panel may have a continuous edge portion, and when applied to a vehicle, it may improve aesthetics by conforming to the specifications of the vehicle body surface e.g., hood, door, lid.

In addition, the dummy cell module may include a heat dissipation layer. Accordingly, heat generated in adjacent solar cell modules may be effectively released to the outside thereof.

As a result, the output characteristics of the solar panel may be improved.

By controlling and regulating the temperature of the solar panel, failures may be prevented, and lifespan characteristics may be improved.

### BRIEF DESCRIPTION OF THE DRAWINGS

The foregoing and other aspects, features, and advantages of the present disclosure, as well as the following detailed description of the embodiments, will be better understood when read in conjunction with the accompanying drawings. For the purpose of illustrating the present disclosure, there is shown in the drawings an exemplary embodiment, it being understood, however, that the present disclosure is not intended to be limited to the details shown because various modifications and structural changes may be made therein without departing from the spirit of the present disclosure and within the scope and range of equivalents of claims. The use of the same reference numerals or symbols in different drawings indicates similar or identical items.

FIG. 1 is a cross-sectional view of a solar panel according to an embodiment of the present disclosure.

FIG. 2 is a cross-sectional view of a dummy cell module according to an embodiment of the present disclosure.

FIG. 3 is a cross-sectional view of a solar cell module according to an embodiment of the present disclosure.

FIG. 4 is a cross-sectional view of a solar panel according to an embodiment of the present disclosure.

FIG. 5 is a cross-sectional view of a dummy cell module according to an embodiment of the present disclosure.

FIG. 6 is a cross-sectional view of a dummy cell module according to an embodiment of the present disclosure.

FIG. 7A is an image of an existing solar panel.

FIG. 7B is an image of the solar panel according to an embodiment of the present disclosure.

### DETAILED DESCRIPTION

Unless otherwise defined, all terms including technical and scientific terms used herein as is customary in the art to which the inventive concept of the present disclosure belongs. It will be further understood that terms in common usage should also be interpreted as is customary in the relevant art and not in an idealized or overly formal sense unless expressly so defined herein.

It will be understood that, although the terms “first,” “second,” and other numerical terms may be used herein to describe various elements, these elements should not be limited by these terms. These terms are only used to distinguish one element from another. For example, a first element could be termed a second element, and similarly, a second element could be termed a first element, without departing from the scope of the present disclosure.

The terminology used herein is used for describing particular exemplary embodiments only and is not intended to be limiting. As used herein, the articles “a,” “an,” and “the,” include plural referents unless the context clearly dictates otherwise. In the following disclosure, the terms “include,” “comprise,” “have,” and the like designate the existence of features, steps, elements, and combinations thereof, but should not be understood as precluding the existence or addition of one or more other features, steps, elements, and combinations thereof.

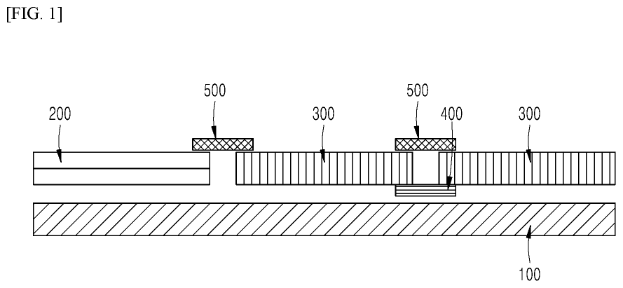

Hereinafter, embodiments of the present disclosure will be described in more detail with reference to the accompanying drawings. In FIGS. 1 to 6, the shape of an edge portion of the solar panel is illustrated, showing a portion composed of one dummy cell module 200 and two solar cell modules 300. This is exemplary and is not limited to a specific size or shape.

First, a solar panel according to an exemplary embodiment of the present disclosure will be described with reference to FIG. 1.

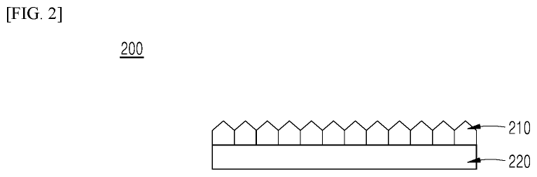

FIG. 1 is a cross-sectional view of a solar panel according to an exemplary embodiment of the present disclosure. In FIG. 1, each component is illustrated arbitrarily for explanatory purposes and does not represent actual size or shape. The same applies to FIGS. 2 to 6.

Referring to FIG. 1, the solar panel of the present disclosure may include a heat transfer layer 100, a dummy cell module 200 disposed over and spaced apart from the heat transfer layer 100, and a solar cell module 300 spaced apart from the dummy cell module 200 in a horizontal direction.

FIG. 2 is a cross-sectional view of a dummy cell module 200 according to an embodiment of the present disclosure.

Referring to FIG. 2, the dummy cell module 200 may include a semiconductor layer 210. The semiconductor layer 210 may include a plurality of semiconductor units. A semiconductor unit may refer to an active layer portion of an existing solar cell structure, excluding the top electrode and the rear electrode. In FIG. 2, the top electrode is omitted.

Referring to FIG. 2, the solar panel may include a heat dissipation layer 220. The heat dissipation layer 220 may include one or more of aluminum, silver, copper, gold and any combination thereof. The heat dissipation layer 220 has excellent thermal conductivity and can release transferred heat into the atmosphere through convection or radiation. The semiconductor layer 210 may be disposed on the heat dissipation layer 220.

The dummy cell module 200 of the present disclosure may not include a rear electrode. Accordingly, the dummy cell module 200 may be in an electrically inactive state. Since the dummy cell module 200 does not include a rear electrode 320, it may have various polygonal shapes, unlike existing solar cell modules. Therefore, the dummy cell module 200 may be positioned at the edge portion of the solar panel, enabling the implementation of a continuously shaped solar panel. Accordingly, when applied to vehicle body surfaces such as hoods, doors, and lids, the solar panel may be shaped to conform to vehicle surface specifications, improving aesthetics.

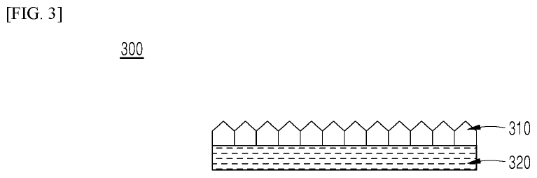

FIG. 3 is a cross-sectional view of a solar cell module 300 according to an embodiment of the present disclosure. Referring to FIG. 3, the solar cell module 300 may include a semiconductor layer 310. The semiconductor layer 310 of the solar cell module 300 is the same as the semiconductor layer 210 of the dummy cell module 200 described above, and the semiconductor layer 310 of the solar cell module 300 may also include a plurality of semiconductor units.

The solar cell module 300 of the present disclosure may include a rear electrode 320. Accordingly, it may be electrically active. In FIG. 3, the top electrode is omitted.

In the present disclosure, a plurality of solar cell modules 300 may be provided.

Furthermore, like the dummy cell module 200, the solar cell modules 300 may be disposed over and spaced apart from the heat transfer layer 100.

The heat transfer layer 100 of the present disclosure may include a thermal interface material (TIM). The thermal interface material is a heat interface material, and refers to a material that facilitates more efficient heat transfer and improves thermal conductivity between two adjacent surfaces. The heat transfer layer 100 of the present disclosure may include a material with excellent thermal conductivity and serve as a pathway for transferring heat generated within the panel to the dummy cell module 200.

In detail, the thermal interface material may be any one selected from the group consisting of thermal grease, thermal tape, a thermal pad, a phase change material PCM, and a metal-based material.

The thermal grease may include a silicone or hydrocarbon base and may further include a thermally conductive filler, such as a metal oxide. Additionally, the thermal grease may be in the form of a soft, viscous paste. The thermal tape may be a thin adhesive tape and may be made of a polymer material. The thermal pad may be in the form of a pad and may be composed of silicone or polymer embedded with a thermally conductive filler. The phase change material (PCM) is a material that absorbs and releases a large amount of heat by transitioning between solid and liquid states, providing the advantage of high thermal conductivity. The metal-based materials refer to metal alloys that provide high thermal conductivity and are suitable for surface irregularities.

Referring to FIG. 1, the heat transfer layer 100 may extend in the direction of the solar cell module 300 to vertically overlap with the solar cell module 300. That is, the dummy cell module 200 and the solar cell module 300 may be disposed over and spaced apart at equal intervals from the heat transfer layer 100 to vertically overlap with the heat transfer layer 100.

When the solar panel of the present disclosure is as shown in FIG. 1, heat generated from the solar cell module 300 is transferred to the heat transfer layer 100, and then transferred toward the heat dissipation layer 220 of the dummy cell module 200 and released into the atmosphere.

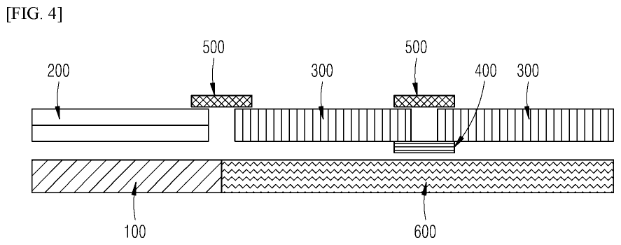

FIG. 4 is a cross-sectional view of a solar panel according to an embodiment of the present disclosure. Referring to FIG. 4, the solar panel may further include a heat absorption layer 600 extending from the heat transfer layer 100 in the direction of the solar cell module 300 to vertically overlap with the solar cell module 300. That is, the heat transfer layer 100 may be disposed to vertically overlap with the dummy cell module 200, and the heat absorption layer 600 may be disposed to vertically overlap with the solar cell module 300. Here, the dummy cell module 200 and the solar cell module 300 may be disposed over and spaced apart at equal intervals from the heat transfer layer 100 and the heat absorption layer 600, respectively. Meanwhile, in FIG. 4, the dummy cell module 200 and the solar cell module 300 are the same as those described above.

When the solar panel of the present disclosure is as shown in FIG. 4, heat generated from the solar cell module 300 is transferred to the heat absorption layer 600 and then transferred to the heat transfer layer 100. Thereafter, the heat is transferred toward the heat dissipation layer 220 of the dummy cell module 200 and is released into the atmosphere.

The heat absorption layer 600 of the present disclosure may include one or more of phase change materials (PCM), thermal fluids, nanofluids and any combination thereof. In one example, the phase change material may be paraffin. In one example, the thermal fluid may be water or ethylene glycol. In one example, the nanofluid may be nano-silver or nano-copper. However, these materials are exemplary and are not limited to specific materials.

Meanwhile, the solar panel of the present disclosure may include an interconnector 400. The interconnector 400 is electrically conductive and may electrically connect a plurality of solar cell modules 300.

Referring to FIGS. 1 and 4, the interconnector 400 may be disposed to connect one end portion of any one solar cell module 300 to one end portion of another solar cell module 300 among the plurality of solar cell modules 300.

In the present disclosure, the solar cell modules 300 are disposed over and spaced apart from the heat transfer layer 100 or the heat absorption layer 600, and the interconnector 400 may be disposed in the space between the heat transfer layer 100 or the heat absorption layer 600 and the solar cell modules 300.

That is, the interconnector 400 may be disposed in the space between the heat transfer layer 100 or the heat absorption layer 600 and the solar cell modules 300 to connect one end portion of any one solar cell module 300 to one end portion of another solar cell module 300.

The solar panel of the present disclosure may further include a cover sheet 500. The cover sheet 500 may improve aesthetics by covering the heat transfer layer 100, the heat absorption layer 600, or the interconnector 400.

In the present disclosure, the cover sheet 500 may be made of an insulating material to prevent short circuits in the solar cell modules 300. In one example, the cover sheet 500 may be in a form of an adhesive tape or sheet.

Referring to FIGS. 1 and 4, the cover sheet 500 may be disposed to vertically overlap with one end portion of any one solar cell module 300 and one end portion of another solar cell module 300 among the plurality of solar cell modules 300, or may be disposed to vertically overlap with one end portion of the dummy cell module 200 and one end portion of any one solar cell module 300 adjacent to the dummy cell module 200.

That is, the cover sheet 500 may be disposed to cover a gap formed as the dummy cell module 200 and the solar cell module 300 are spaced apart in the horizontal direction, connecting one end portion of the dummy cell module 200 to one end portion of the solar cell module 300.

In addition, the cover sheet 500 may be disposed to cover a gap formed as the plurality of solar cell modules 300 are spaced apart in a horizontal direction, connecting one end portion of any one solar cell module 300 to one end portion of another solar cell module 300. Here, for the example of a cover sheet 500 disposed to connect a plurality of solar cell modules 300, the cover sheet 500 may vertically overlap with the interconnector 400 with the solar cell modules 300 interposed therebetween.

Meanwhile, the dummy cell module 200 according to an embodiment of the present disclosure may further include a heat transfer layer 230 inside the dummy cell module 200. Here, the dummy cell module 200 may not include a heat dissipation layer 220, and a semiconductor layer 210 may be disposed on the heat transfer layer 230 inside the dummy cell module 200.

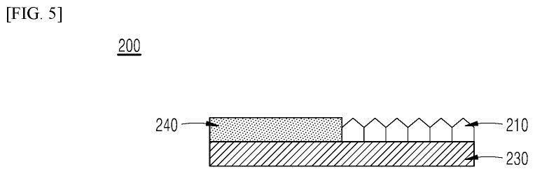

FIG. 5 is a cross-sectional view of the dummy cell module 200 according to an embodiment of the present disclosure.

Referring to FIG. 5, the dummy cell module 200 may include a heat dissipation member 240 on at least a portion of the heat transfer layer 230 inside the dummy cell module 200. In the present disclosure, the heat dissipation member 240 may be made of a material with an emissivity of 0.9 or higher. In detail, carbon materials, ceramic materials, asphalt, and the like may be used, but the present disclosure is not limited thereto.

In an embodiment of the present disclosure, the heat transfer layer 230 may include a first region and a second region, wherein the semiconductor layer 210 is disposed on the first region, and the heat dissipation member 240 is disposed on the second region.

Referring to FIG. 5, the first region and the second region are partitioned so that the semiconductor layer 210 may be continuously disposed on the first region, and the heat dissipation member 240 may be continuously disposed on the second region.

When the dummy cell module 200 of the present disclosure is as shown in FIG. 5, heat generated from the solar cell module 300 is transferred to the heat absorption layer 600. Thereafter, the heat is transferred to the heat transfer layer 100, 230 and then moves toward the heat dissipation member 240 of the dummy cell module 200, and is finally released into the atmosphere.

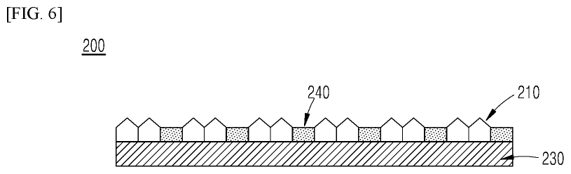

FIG. 6 is a cross-sectional view of the dummy cell module 200 according to an embodiment of the present disclosure.

Referring to FIG. 6, the dummy cell module 200 may include a heat dissipation member 240 on at least a portion of the heat transfer layer 230 inside the dummy cell module 200. In the present disclosure, the heat dissipation member 240 may be made of a material with an emissivity of 0.9 or higher. In detail, carbon materials, ceramic materials, asphalt, and the like may be used, but the present disclosure is not limited thereto.

Referring to FIG. 6, the first region and the second region may be disposed alternately and repeatedly. That is, the first and second regions may be disposed without a fixed rule, allowing the semiconductor layer 210 and the heat dissipation member 240 to be alternately disposed.

When the dummy cell module 200 of the present disclosure is as shown in FIG. 6, heat generated from the solar cell module 300 is transferred to the heat absorption layer 600. Thereafter, the heat is transferred to the heat transfer layer 100, 230 and then moves toward the heat dissipation member 240 of the dummy cell module 200, and is finally released into the atmosphere.

The dummy cell module 200 according to the various embodiments described above may be disposed at the edge portion of the solar panel. Accordingly, the solar panel of the present disclosure may include a continuous edge portion.

Since the dummy cell module 200 of the present disclosure does not include a rear electrode 320 and is electrically inactive, its shape may be freely varied. For example, dummy cell module 200 may be in a form of a right-angled triangle, a rectangle, a square, or an equilateral triangle, but the present disclosure is not limited thereto. by being capable of having various shapes, the dummy cell module 200 may be manufactured to match the specifications of vehicle body surfaces such as hoods, doors, and lids.

Previously, when only existing rectangular solar cell modules were used in a solar panel, cracks would often occur at the edge portions when applied to contoured vehicle body surfaces. However, by including the dummy cell module 200, the present disclosure allows for the manufacture of components in shapes that match required specifications, and improving the crack occurrence phenomenon.

Additionally, since the solar panel includes a continuous edge portion rather than a stepped edge portion, aesthetics may be enhanced.

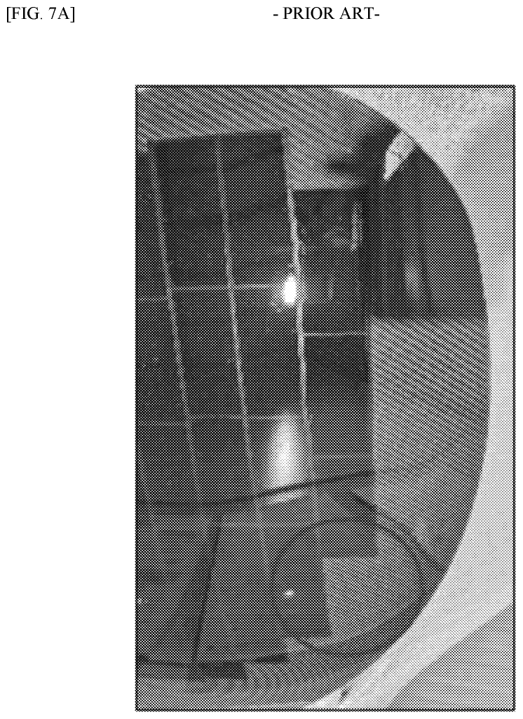

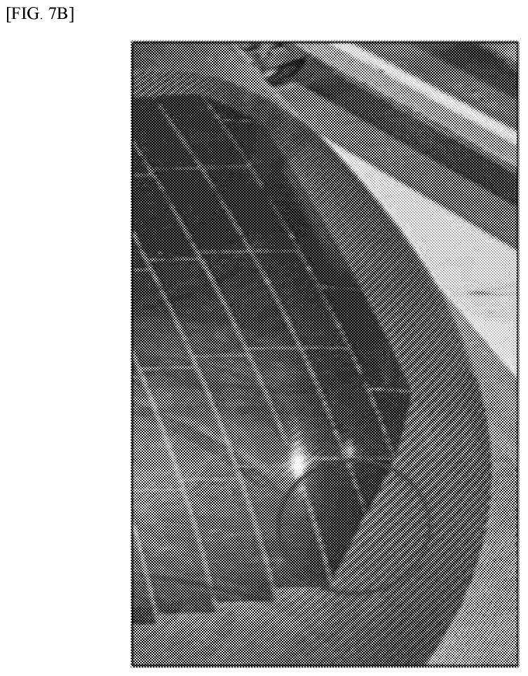

This difference is illustrated in FIG. 7A and FIG. 7B.

FIG. 7A is an image of an existing solar panel, and FIG. 7B is an image of a solar panel according to an embodiment of the present disclosure.

Referring to FIGS. 7A and 7B, it may be seen that the solar panel of the present disclosure includes a continuous edge portion, providing superior aesthetics compared to the existing solar panel with a stepped edge portion.

A vehicle according to an exemplary embodiment of the present disclosure may include the solar panel according to the various embodiments described above. Accordingly, the aesthetics of the vehicle may be improved, and its lifespan characteristics and output characteristics may also be enhanced.

The present disclosure has been shown and described with reference to exemplary embodiments thereof. In this regard, it will be understood by one of ordinary skill in the art that various changes in form and details may be made therein without departing from the scope of the disclosure. Therefore, the disclosed exemplary embodiments should be considered in a descriptive sense only and not in a limiting sense. The scope of the disclosure is defined not by the detailed foregoing description but by the following claims, and all differences within the scope will be construed as being included in the disclosure.

### DESCRIPTION OF SYMBOLS

100: Heat transfer layer
200: Dummy cell module
210: Semiconductor layer
220: Heat dissipation layer
230: Heat transfer layer
240: Heat dissipation member
300: Solar cell module
310: Semiconductor layer
320: Rear electrode
400: Interconnector
500: Cover sheet
600: Heat absorption layer

1. A solar panel comprising:
a heat transfer layer;
a dummy cell module disposed over and spaced apart from the heat transfer layer; and
a solar cell module spaced apart from the dummy cell module in a horizontal direction of the solar panel,
wherein the dummy cell module is electrically inactive,
wherein the dummy cell module comprises a semiconductor layer and a heat dissipation member disposed inside the dummy cell module, and
wherein the heat dissipation member has an emissivity of 0.9 or higher.

2. The solar panel of claim 1, wherein the heat transfer layer extends in a vertical direction of the solar panel to vertically overlap with the solar cell module.

3. The solar panel of claim 1, further comprising a heat absorption layer extending from the heat transfer layer in a direction of the solar cell module to vertically overlap with the solar cell module.

4. The solar panel of claim 3,
wherein the dummy cell module further comprises a heat dissipation layer and
wherein the heat dissipation layer is disposed to face the heat transfer layer.

5. The solar panel of claim 1,
wherein the solar cell module is plural and the plurality of solar cell modules are spaced apart from each other in the horizontal direction, and
wherein the solar panel further comprises an interconnector disposed to connect one end portion of any one solar cell module to one end portion of another solar cell module among the plurality of solar cell modules.

6. The solar panel of claim 5, further comprising a cover sheet disposed to vertically overlap with one end portion of any one solar cell module and one end portion of another solar cell module among the plurality of solar cell modules, or disposed to vertically overlap with one end portion of the dummy cell module and one end portion of any one solar cell module adjacent to the dummy cell module.

7. The solar panel of claim 1, wherein the heat transfer layer comprises a thermal interface material (TIM).

8. The solar panel of claim 3, wherein the heat absorption layer comprises one or more of phase change materials (PCM), thermal fluids, nanofluids and any combination thereof.

9. The solar panel of claim 1, wherein the dummy cell module does not comprise a rear electrode.

10. The solar panel of claim 1,
wherein the dummy cell module comprises a heat dissipation layer,
wherein the heat dissipation layer comprises one or more of aluminum, silver, copper, gold and any combination thereof.

11. The solar panel of claim 1, wherein the dummy cell module further comprises a heat transfer layer disposed inside the dummy cell module.

12. The solar panel of claim 11,
wherein the semiconductor layer is disposed on the heat transfer layer inside the dummy cell module.

13. The solar panel of claim 12, wherein the dummy cell module comprises the heat dissipation member disposed on at least a portion of the heat transfer layer inside the dummy cell module.

14. (canceled)

15. The solar panel of claim 13,
wherein the heat transfer layer inside the dummy cell module comprises a first region and a second region,
wherein the semiconductor layer is disposed on the first region and the heat dissipation member is disposed on the second region.

16. The solar panel of claim 15, wherein the first region and the second region are disposed alternately in the horizontal direction.

17. The solar panel of claim 1, wherein the dummy cell module is disposed at an edge portion of the solar panel and includes a continuous edge portion.

18. A vehicle comprising the solar panel of claim 1.
